(19) United States
(12) Patent Application Publication
(10) Pub. No.: US 2022/0238335 A1
(43) Pub. Date: Jul. 28, 2022

(54) METHOD FOR FORMING FILM AND PROCESSING APPARATUS

(71) Applicant: Tokyo Electron Limited, Tokyo (JP)

(72) Inventors: Takeshi OYAMA, Yamanashi (JP); Kiwamu ITO, Yamanashi (JP); Yamato TONEGAWA, Yamanashi (JP)

(21) Appl. No.: 17/647,185

(22) Filed: Jan. 6, 2022

(30) Foreign Application Priority Data
Jan. 28, 2021 (JP) 2021-011976

(51) Int. Cl. H01L 21/02; H01J 37/32; C23C 16/36; C23C 16/34; C23C 16/455

(52) U.S. Cl. CPC H01L 21/02304; H01L 21/02167; H01L 21/0217; H01L 21/02274; H01J 2237/332; H01J 37/32449; C23C 16/36; C23C 16/345; C23C 16/45536; H01L 21/0228

(57) ABSTRACT

A method for forming a film, the method including: forming a SiCN seed layer on a substrate by a thermal ALD, forming a SiN protective layer on the SiCN seed layer by a thermal ALD, and forming a SiN bulk layer on the SiN protective layer by a plasma enhanced ALD.

### CROSS-REFERENCE TO RELATED APPLICATIONS

The present application is based on and claims priority to Japanese Patent Application No. 2021-011976 filed on Jan. 28, 2021, the contents of which are incorporated herein by reference in their entirety.

### TECHNICAL FIELD

The disclosures herein generally relate to a method for forming a film, and a processing apparatus.

### BACKGROUND

A method for forming a silicon nitride film in which ammonia gas, a silane family gas, and a carbon hydride gas are used as process gases, and the silane family gas is intermittently supplied, is known (see, for example, Japanese Unexamined Patent Application Publication No. 2005-012168).

### SUMMARY

According to an embodiment, a method for forming a film includes: forming a SiCN seed layer on a substrate by a thermal ALD (atomic layer deposition), forming a SiN protective layer on the SiCN seed layer by a thermal ALD, and forming a SiN bulk layer on the SiN protective layer by a plasma enhanced ALD.

### BRIEF DESCRIPTION OF THE DRAWINGS

FIG. 1 is a diagram illustrating an outline (1) of an example of a processing apparatus according to an embodiment;

FIG. 2 is a diagram illustrating an outline (2) of the example of the processing apparatus according to the embodiment;

FIG. 3 is a flow chart illustrating an example of a method for forming a film according to the embodiment;

FIGS. 4A to 4C are cross-sectional views illustrating a process of an example of the method for forming a film according to the embodiment;

FIG. 5 is a diagram illustrating an example of a process for forming a SiCN seed layer by a thermal ALD;

FIG. 6 is a diagram illustrating an example of a process for forming a SiN protective layer by a thermal ALD;

FIG. 7 is a diagram illustrating an example of a process for forming a SiN bulk layer by a plasma enhanced ALD;

FIG. 8 is a diagram illustrating another example of a process for forming a SiN bulk layer by a plasma enhanced ALD;

FIGS. 9A and 9B are diagrams illustrating a reaction when a Si/SiCN stack is exposed to NH₃ plasma;

FIGS. 10A and 10B are diagrams illustrating a reaction when a Si/SiCN/SiN protective layer stack is exposed to NH₃ plasma;

FIG. 11 is a diagram illustrating a result of evaluating plasma resistance of a SiCN seed layer; and

FIG. 12 is a diagram illustrating a result of evaluating a composition of the SiCN seed layer.

### DETAILED DESCRIPTION

Hereinafter, non-limiting exemplary embodiments of the present disclosure will be described with reference to the accompanying drawings. In the drawings, the same or corresponding parts or components are designated by the same or corresponding reference numerals, and the description thereof will be omitted.

### [Processing Apparatus]

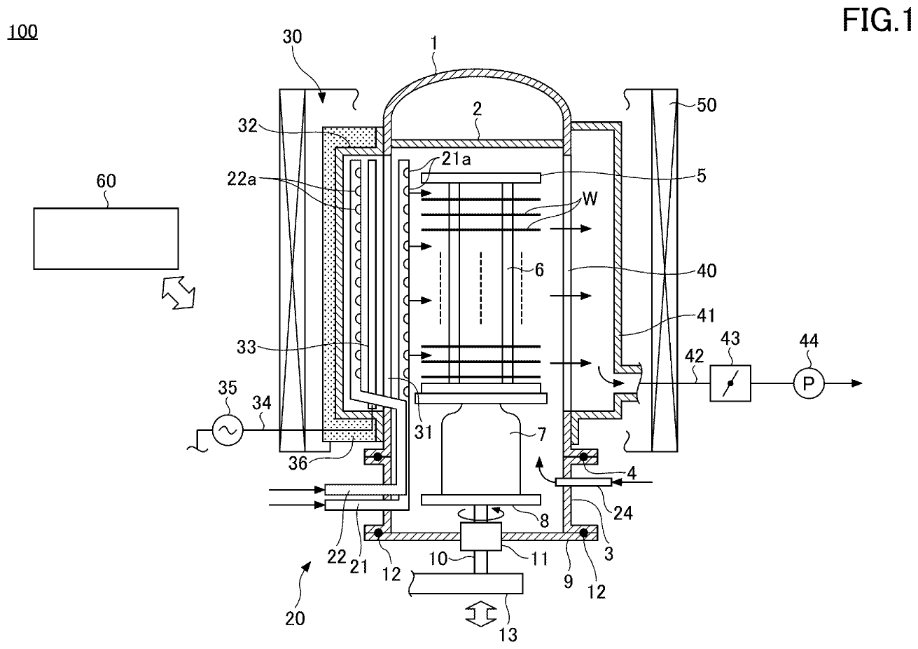

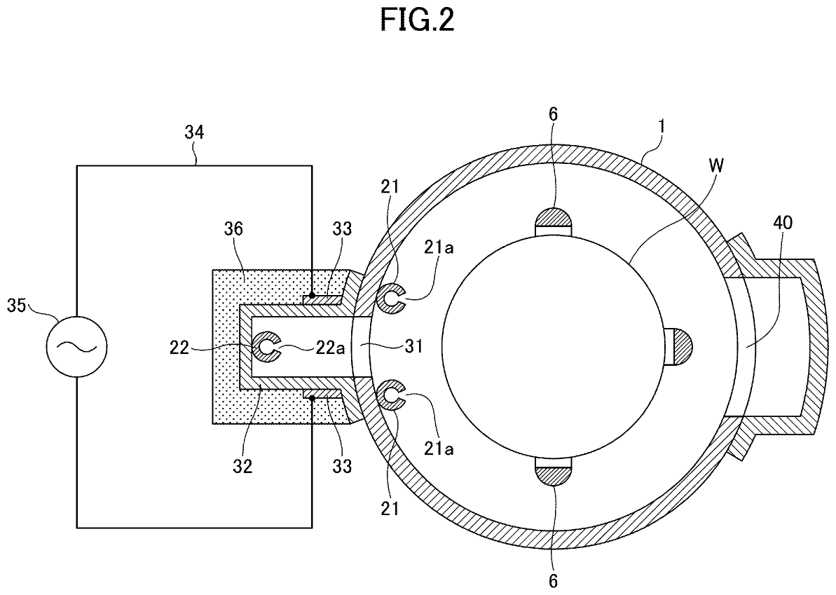

Referring to FIGS. 1 and 2, an example of a processing apparatus according to an embodiment will be described.

A processing apparatus 100 includes a processing chamber 1 having a cylindrical shape with a ceiling and an open lower end. The entire processing chamber 1 is formed, for example, of quartz. Near the upper end of the processing chamber 1, a ceiling plate formed of quartz is provided, thereby sealing the space under the ceiling plate 2. To an opening of the lower end of the processing chamber 1, a metal manifold 3 having a cylindrical shape is connected via a sealing member 4 such as an O-ring.

The manifold 3 supports the lower end of the processing chamber 1. A boat 5 is inserted into the processing chamber 1 from below the manifold 3. The boat 5 has a configuration in which a large number of substrates W (for example, 25 to 150) are mounted in multiple stages. The substrates W are housed substantially horizontally in the processing chamber 1 with spacing from each other along the vertical direction. The boat 5 is formed, for example, of quartz. The boat 5 includes three rods 6 (see FIGS. 1 and 2). The substrates W are supported by grooves (not shown) formed in the rods 6. The substrate W may be, for example, a semiconductor wafer.

The boat 5 is mounted on a table 8 via a heat insulating tube 7 formed of quartz. The table 8 is supported on a rotating shaft 10. The rotating shaft penetrates a metal (stainless steel) lid 9 that opens and closes the lower end of the manifold 3.

A magnetic fluid seal 11 is provided at the penetrating portion of the rotating shaft 10. The magnetic fluid seal 11 airtightly seals the rotating shaft 10 and rotatably supports the rotating shaft 10. A seal member 12 is provided between the periphery of the lid 9 and the lower end of the manifold 3 to maintain the airtightness within the processing chamber 1.

The rotating shaft 10 is mounted to the tip of an arm 13. The arm 13 is supported by a lifting mechanism (not shown), such as a boat elevator. The boat 5 and the lid 9 are integrally elevated and lowered, and are inserted into and removed from the inside of the processing chamber 1. The table 8 may be fixed to the lid 9, and the substrate W may be processed without rotating the boat 5.

The processing apparatus 100 includes a gas supply 20 for supplying a predetermined gas, such as process gas, purge gas, and the like, into the processing chamber 1.

The gas supply 20 includes gas supply lines 21, 22, and 24. The gas supply lines 21, 22, and 24 are formed, for example, of quartz. The gas supply lines 21 and 22 penetrate the side wall of the manifold 3 inward, then bend upwardly and extend vertically. In each of the vertically-extending portions of the gas supply lines 21 and 22, a plurality of gas holes 21a and 22a are formed at predetermined intervals. The gas holes 21a and 22a are formed in the part of the gas supply lines 21 and 22 that corresponds horizontally to the position where the boat 5 supports the substrates W. The gas holes 21a and 22a discharge gas horizontally. The gas supply line 24 is, for example, a short quartz tube that is provided through the side wall of the manifold 3. In the illustrated examples, two gas supply lines 21 and one line each for gas supply lines 22 and 24 are provided.

The vertically-extending portion of the gas supply line 21 is provided inside the processing chamber 1. A silicon-containing gas from a silicon-containing gas source is supplied via a gas line to the gas supply line 21. The gas line is provided with a flow controller and an open/close valve. Thus, the silicon-containing gas is supplied from the silicon-containing gas source via the gas line and the gas supply line 21 into the processing chamber 1 at a predetermined flow rate.

As the silicon-containing gas, one or more gases selected from the group consisting of, for example, hexachlorodisilane (HCD), monosilane (SiH₄), disilane (Si₂H₆), dichlorosilane (DCS), hexaethylaminodisilane, hexamethyldisilazane (HMDS), tetrachlorosilane (TCS), disilylanine (DSA), trisilylamine (TSA), and bistertialbutylaminosilane (BTBAS) may be used.

A carbon-containing gas from a carbon-containing gas source is also supplied via a gas line to the gas supply line 21. The gas line is provided with a flow controller and an open/close valve. Thus, the carbon-containing gas is supplied from the carbon-containing gas source via the gas line and the gas supply line 21 into the processing chamber 1 at a predetermined flow rate.

As the carbon-containing gas, one or more gases selected from the group consisting of, for example, acetylene (C₂H₂), ethylene (C₂H₄), propylene (C₃H₆), methane (CH₄), ethane (C₂H₆), propane (C₃H₈), and butane (C₄H₁₀) may be used.

The vertically-extending portion of the gas supply line 22 is provided in a plasma generation space described later. A nitrogen-containing gas from a nitrogen-containing gas source is supplied via a gas line to the gas supply line 22. The gas line is provided with a flow controller and an open/close valve. Thus, the nitrogen-containing gas is supplied from the nitrogen-containing gas source via the gas line and the gas supply line 22 to the plasma generation space at a predetermined flow rate. The nitrogen-containing gas is formed into a plasma in the plasma generation space, and then supplied into the processing chamber 1.

As the nitrogen-containing gas, one or more gases selected from the group consisting of, for example, ammonia (NH₃), diazene (N₂H₂), hydrazine (N₂H₄), and an organic hydrazine compound such as monomethylhydrazine (CH₃(NH)NH₂) may be used.

A hydrogen (H₂) gas is also supplied from a hydrogen gas source via a gas line to the gas supply line 22. The gas line is provided with a flow controller and an open/close valve. Thus, the H₂ gas is supplied from the hydrogen gas source via the gas line and the gas supply line 22 to the plasma generation space at a predetermined flow rate. The H₂ gas is formed into a plasma in the plasma generation space, and then supplied into the processing chamber 1.

A purge gas is supplied from a purge gas source via a gas line to the gas supply line 24. The gas line is provided with a flow controller and an open/close valve. Thus, the purge gas is supplied from the purge gas source via the gas line and the gas supply line 24 into the processing chamber 1 at a predetermined flow rate. As the purge gas, for example, an inert gas such as nitrogen (N₂) and argon (Ar) may be used. The purge gas may also be supplied from at least one of the gas supply lines 21 and 22.

A plasma generation mechanism 30 is formed in a part of the side wall of the processing chamber 1. The plasma generation mechanism 30 forms an NH₃ gas into a plasma, thereby generating active species (reactive species) for nitridation. The plasma generation mechanism 30 forms a H₂ gas into a plasma, thereby generating a hydrogen (H) radical. The plasma generation mechanism 30 forms a Cl₂ gas into a plasma, thereby generating a chlorine (Cl) radical.

The plasma generation mechanism 30 includes a plasma compartment wall 32, a pair of plasma electrodes 33, a power supply line 34, an RF power supply 35, and an insulation cover 36.

The plasma compartment wall 32 is airtightly welded to an outer wall of the processing chamber 1. The plasma compartment wall 32 is formed, for example, of quartz. The plasma compartment wall 32 has a concave shape in cross-section, and covers an opening 31 formed in the side wall of the processing chamber 1. The opening 31 is elongated vertically so as to cover vertically all the substrates W supported on the boat 5. The inner space defined by the plasma compartment wall 32 and communicating with the inside of the processing chamber 1, is the plasma generation space. The gas supply line 22 is disposed in the plasma generation space. The gas supply line 21 is disposed close to the substrate W, along the inner wall of the processing chamber 1 outside of the plasma generation space. In the illustrated example, two gas supply lines are disposed at positions sandwiching the opening 31, but the configuration is not limited thereto. For example, only one of the two gas supply lines 21 may be disposed.

A pair of plasma electrodes 33, each having an elongated shape, are disposed facing each other on the outer surface of both sides of the plasma compartment wall 32 along the vertical direction. The power supply line 34 is connected to the lower end of each of the plasma electrodes 33.

The power supply line 34 electrically connects each of the plasma electrodes 33 to the RF power supply 35. In the illustrated example, one end of the power supply line 34 is connected to the lower end of the plasma electrode 33, namely, to the lateral portion of the short side of the plasma electrode 33, and the other end is connected to the RF power supply 35.

The RF power supply 35 is connected to the lower end of each of the plasma electrodes 33 via the power supply line 34. The RF power supply 35 may supply RF power of, for example, 13.56 MHz, to a pair of plasma electrodes 33. Accordingly, RF power is applied within the plasma generation space defined by the plasma compartment wall 32. The nitrogen-containing gas discharged from the gas supply line 22 is formed into a plasma in the plasma generation space to which the RF power is applied, whereby active species for nitridation are generated. The active species are supplied into the processing chamber 1 via the opening 31. The H₂ gas discharged from the gas supply line 22 is formed into a plasma in the plasma generation space to which RF power is applied, whereby a hydrogen radical is generated. The hydrogen radical is supplied into the processing chamber 1 via the opening 31.

The insulation cover 36 is mounted outside the plasma compartment wall 32 to cover the plasma compartment wall 32. A coolant passage (not shown) is provided inside the insulation cover 36. The plasma electrode 33 may be cooled by flowing a cooled coolant, such as N₂ gas, through the coolant passage. A shield (not shown) may be provided between the plasma electrode 33 and the insulation cover 36, to cover the plasma electrode 33. The shield is formed of a good conductor such as metal, and is grounded.

The side wall of the processing chamber 1 facing the opening 31 is provided with an exhaust port 40 for vacuum exhausting the processing chamber 1. The exhaust port 40 is elongated vertically, corresponding to the boat 5. To the portion of the processing chamber 1 where the exhaust port 40 is provided, an exhaust port cover member 41 is attached. The exhaust port cover member 41 is formed in a U-shaped cross section so as to cover the exhaust port 40. The exhaust port cover member 41 extends upwardly along the side wall of the processing chamber 1. To the lower portion of the exhaust port cover member 41, an exhaust line 42 for evacuating the processing chamber 1 via the exhaust port 40 is connected. To the exhaust line 42, an exhaust apparatus 44 that includes a pressure control valve 43 for controlling the pressure in the processing chamber 1, a vacuum pump, and the like, is connected. The exhaust apparatus 44 evacuates the processing chamber 1 via the exhaust line 42.

A cylindrical heating mechanism 50 is provided around the processing chamber 1. The heating mechanism 50 heats the processing chamber 1 and the substrates W inside the processing chamber 1.

The processing apparatus 100 includes a controller 60. The controller 60 controls, for example, an operation of each part of the processing apparatus 100 to perform a method for forming a film to be described later. The controller 60 may be, for example, a computer or the like. A program for a computer to perform an operation of each part of the processing apparatus 100 is stored in a storage medium. The storage medium may be, for example, a flexible disk, a compact disk, a hard disk, a flash memory, a DVD, or the like.

### [Method for Forming a Film]

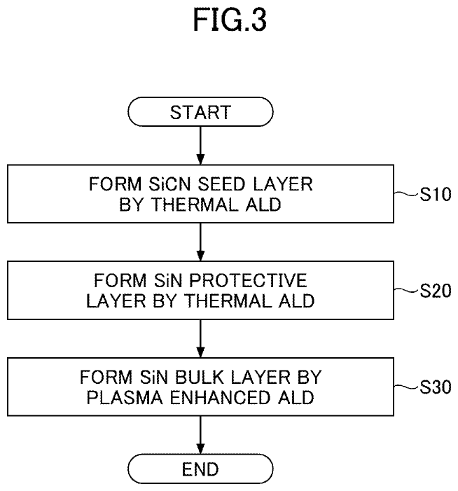

Referring to FIGS. 3 to 8, a method for forming a film according to the embodiment will be described by exemplifying a case where the method is performed by the processing apparatus 100 described above. The method for forming a film according to the embodiment may be performed by an apparatus different from the processing apparatus 100 described above.

The method for forming a film according to the embodiment includes Step S10 of forming a SiCN seed layer by a thermal ALD, Step S20 of forming a SiN protective layer by a thermal ALD, and Step S30 of forming a SiN bulk layer by a plasma enhanced ALD, as shown in FIG. 3.

Step S10 of forming a SiCN seed layer by a thermal ALD, Step S20 of forming a SiN protective layer by a thermal ALD, and Step S30 of forming a SiN bulk layer by a plasma enhanced ALD, are all performed in the processing chamber 1 of the processing apparatus 100, for example.

Step S10 of forming a SiCN seed layer by a thermal ALD, Step S20 of forming a SiN protective layer by a thermal ALD, and Step S30 of forming a SiN bulk layer by a plasma enhanced ALD, are performed in a state where the substrates W are heated to 450° C. to 630° C., for example.

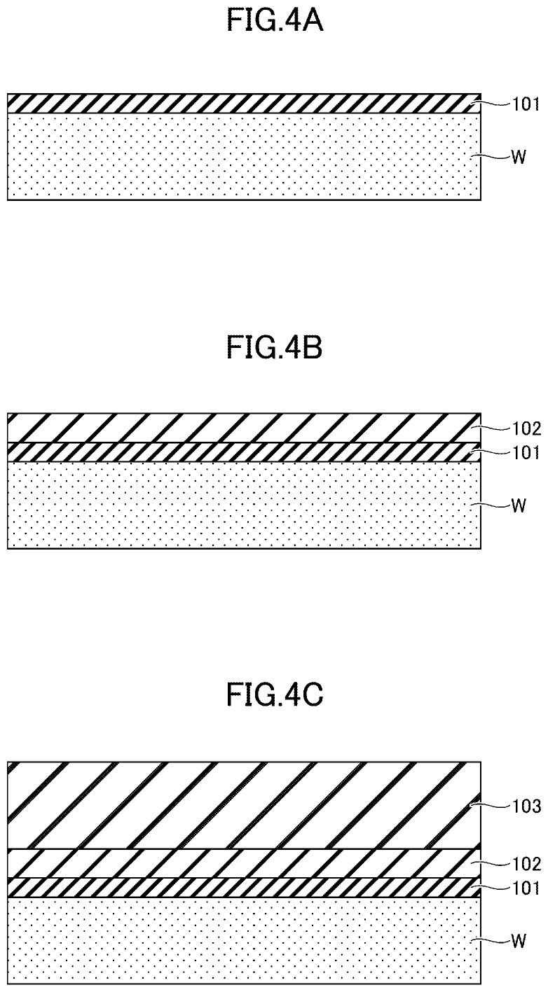

In Step S10 of forming a SiCN seed layer by a thermal ALD, as shown in FIG. 4A, a SiCN seed layer 101 is formed on the substrate W by a thermal ALD (atomic layer deposition) in which the reaction of a silicon-containing gas, a carbon-containing gas, and a nitrogen-containing gas is caused by heat. In other words, in Step S10 of forming the SiCN seed layer by the thermal ALD, the SiCN seed layer 101 is formed on the substrate W without forming the silicon-containing gas, the carbon-containing gas, and the nitrogen-containing gas into a plasma. The substrate W may be, for example, a silicon wafer having a SiO₂ film formed on the surface as a base.

In the present embodiment, Step S10 of forming the SiCN seed layer by the thermal ALD includes, as shown in FIG. 5, a purge step S11, a HCD supply step S12, a purge step S13, a C₂H₄ supply step S14, a purge step S15, and a Th—NH₃ supply step S16. The purge step S11, the HCD supply step S12, the purge step S13, the C₂H₄ supply step S14, the purge step S15, and the Th—NH₃ supply step S16 are repeated in this order until the SiCN seed layer 101 of a desired thickness is formed on the substrate W. The number of the repeats may be, for example, from 1 to 20.

In the purge step S11, the atmosphere in the processing chamber 1 is replaced with a purge gas. Specifically, the atmosphere in the processing chamber 1 is replaced with the purge gas by supplying the purge gas from the gas supply line 24 to the processing chamber 1 while evacuating the processing chamber 1 by the exhaust apparatus 44.

In the HCD supply step S12, a HCD gas, which is an example of a silicon-containing gas, is supplied to the substrate W. Specifically, the HCD gas is supplied from the gas supply line 21 into the processing chamber 1. As a result, the HCD gas adsorbs to the surface of the substrate W.

In the purge step S13, the atmosphere in the processing chamber 1 is replaced with a purge gas. Specifically, the atmosphere in the processing chamber 1 is replaced with the purge gas by supplying the purge gas from the gas supply line 24 to the processing chamber 1 while evacuating the processing chamber 1 by the exhaust apparatus 44.

In the C₂H₄ supply step S14, a C₂H₄ gas, which is an example of a carbon-containing gas, is supplied to the substrate W. Specifically, the C₂H₄ gas is supplied to the substrate W by supplying the C₂H₄ gas into the processing chamber 1 from the gas supply line 22. As a result, the HCD gas adsorbed to the surface of the substrate W is carbonized.

In the purge step S15, the atmosphere in the processing chamber 1 is replaced with a purge gas. Specifically, the atmosphere in the processing chamber 1 is replaced with the purge gas by supplying the purge gas from the gas supply line 24 to the processing chamber 1 while evacuating the processing chamber 1 by the exhaust apparatus 44.

In the Th—NH₃ supply step S16, an NH₃ gas, which is an example of a nitrogen-containing gas, is supplied to the substrate W. Specifically, the NH₃ gas is supplied to the substrate W by supplying the NH₃ gas into the processing chamber 1 from the gas supply line 22. As a result, the HCD gas adsorbed to the surface of the substrate W is nitrided.

In Step S20 of forming a SiN protective layer by a thermal ALD, as shown in FIG. 4B, a SiN protective layer 102 is formed on the SiCN seed layer 101 by a thermal ALD in which the reaction of a silicon-containing gas and a nitrogen-containing gas is caused by heat. In other words, in Step S20 of forming the SiN protective layer by the thermal ALD, the SiN protective layer 102 is formed on the SiCN seed layer 101 without forming the silicon-containing gas and the nitrogen-containing gas into a plasma.

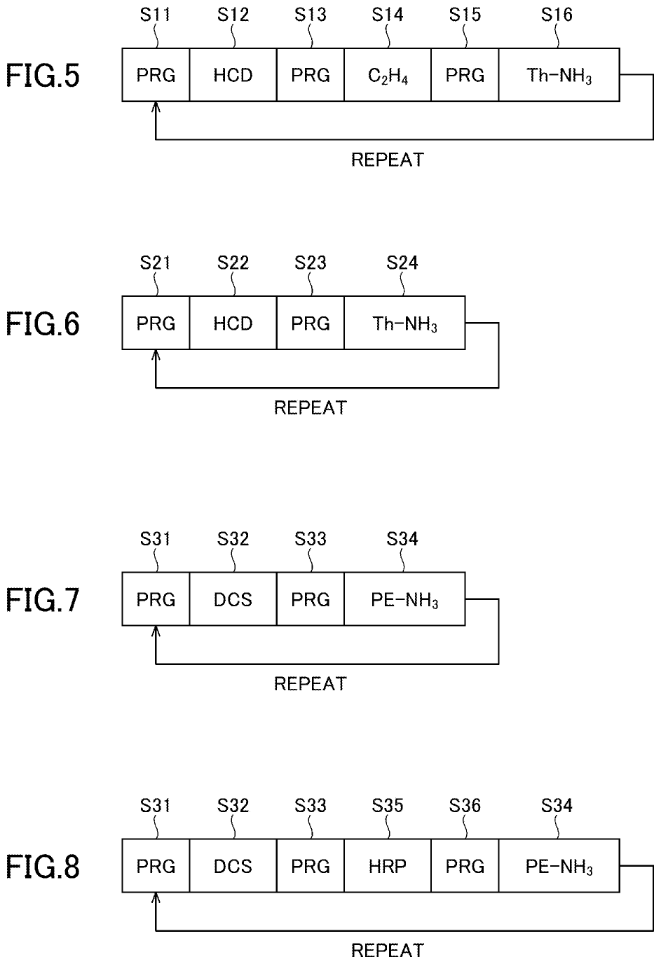

In the present embodiment, Step S20 of forming the SiN protective layer by the thermal ALD includes, as shown in FIG. 6, a purge step S21, a HCD supply step S22, a purge step S23, and a Th—NH₃ supply step S24. The purge step S21, the HCD supply step S22, the purge step S23, and the Th—NH₃ supply step S24 are repeated in this order until the SiN protective layer 102 of a desired thickness is formed on the SiCN seed layer 101. The number of the repeats may be, for example, from 5 to 20.

The thickness of the SiN protective layer 102 is preferably 2 nm or more. Accordingly, damage to the SiCN seed layer 101 when a SiN bulk layer 103 is formed on the SiN protective layer 102 by the plasma enhanced ALD is greatly reduced. In addition, it is preferable that the SiN protective layer 102 is thin, because the SiN layer formed by the thermal ALD tends to have a poorer film quality compared to the SiN layer formed by the plasma enhanced ALD. The thickness of the SiN protective layer 102 is, for example, 3 nm or less.

The purge step S21, the HCD supply step S22, the purge step S23, and the Th—NH₃ supply step S24 may be the same as the purge step S11, the HCD supply step S12, the purge step S13, and the Th—NH₃ supply step S16, respectively.

In Step S30 of forming a SiN bulk layer by a plasma enhanced ALD, as shown in FIG. 4C, a SiN bulk layer 103 is formed on the SiN protective layer 102 by a plasma enhanced ALD in which the reaction of a silicon-containing gas and a nitrogen-containing gas is assisted by a plasma.

In the present embodiment, Step S30 of forming the SiN bulk layer by the plasma enhanced ALD includes, as shown in FIG. 7, a purge step S31, a DCS supply step S32, a purge step S33, and a PE-NH₃ supply step S34. The purge step S31, the DCS supply step S32, the purge step S33, and the PE-NH₃ supply step S34 are repeated in this order until the SiN bulk layer 103 of a desired thickness is formed on the SiN protective layer 102.

The purge step S31 and the purge step S33 may be the same as the purge step S11 and the purge step S13, respectively.

In the DCS supply step S32, a DCS gas, which is an example of a silicon-containing gas, is supplied to the substrate W. Specifically, the DCS gas is supplied into the processing chamber 1 from the gas supply line 21. As a result, the DCS gas adsorbs to the surface of the substrate W.

In the PE-NH₃ supply step S34, the substrate W is exposed to a plasma generated from the NH₃ gas, which is an example of a nitrogen-containing gas. Specifically, by supplying the NH₃ gas from the gas supply line 22 into the processing chamber 1, and by applying an RF power to a pair of plasma electrodes 33 from the RF power supply 35, the NH₃ gas is formed into a plasma, and active species for nitridation are generated. The active species are supplied to the substrate W. As a result, the DCS gas adsorbed to the surface of the substrate W is nitrided.

Step S30 of forming a SiN bulk layer by plasma enhanced ALD may further include a HRP step S35 and a purge step S36, in addition to the purge step S31, the DCS supply step S32, the purge step S33, and the PE-NH₃ supply step S34, as shown in FIG. 8. In this case, the purge step S31, the DCS supply step S32, the purge step S33, the HRP step S35, the purge step S36, and the PE-NH₃ supply step S34 are repeated in this order until the SiN bulk layer 103 of a desired thickness is formed on the SiN protective layer 102. The addition of the HRP step S35 improves the film quality of the SiN bulk layer 103.

In the HRP step S35, HRP (Hydrogen Radical Purge) is performed so that the substrate W is exposed to a plasma generated from the H₂ gas. In the present embodiment, by supplying the H₂ gas from the gas supply line 22 into the processing chamber 1, and by applying an RF power to a pair of plasma electrodes 33 from the RF power supply 35, the H₂ gas is formed into a plasma, and hydrogen radicals are generated. The hydrogen radicals are supplied to the substrate W.

In the purge step S36, the atmosphere in the processing chamber 1 is replaced with a purge gas. Specifically, the atmosphere in the processing chamber 1 is replaced with the purge gas by supplying the purge gas from the gas supply line 24 to the processing chamber 1 while evacuating the processing chamber 1 by the exhaust apparatus 44.

As described above, according to the method for forming a film of the present embodiment, the SiN protective layer 102 is formed by the thermal ALD prior to forming the SiN bulk layer 103 by the plasma enhanced ALD on the SiCN seed layer 101. The SiN protective layer 102 serves to block the plasma when the SiN bulk layer 103 is formed by the plasma enhanced ALD. Accordingly, the film quality of the SiCN seed layer 101 is maintained. That is, damage to the SiCN seed layer 101 can be reduced when forming the SiN bulk layer 103 on the SiCN seed layer 101 using a plasma.

In the method for forming a film according to the embodiment described above, a case in which different types of silicon-containing gases are used in Steps S10 and S20 versus Step S30, has been described. The present disclosure is not limited thereto. For example, in Step S10, Step S20, and Step S30, the same type of silicon-containing gas may be used. For example, in Step S10, Step S20, and Step S30, different types of silicon-containing gases may be used.

In the method for forming a film according to the embodiment described above, Step S10, Step S20, and Step S30 are all performed in the processing chamber 1. The present disclosure is not limited thereto.

### [Mechanism]

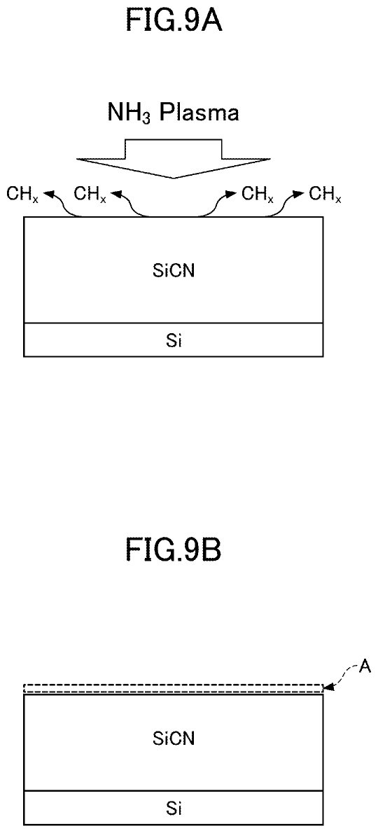

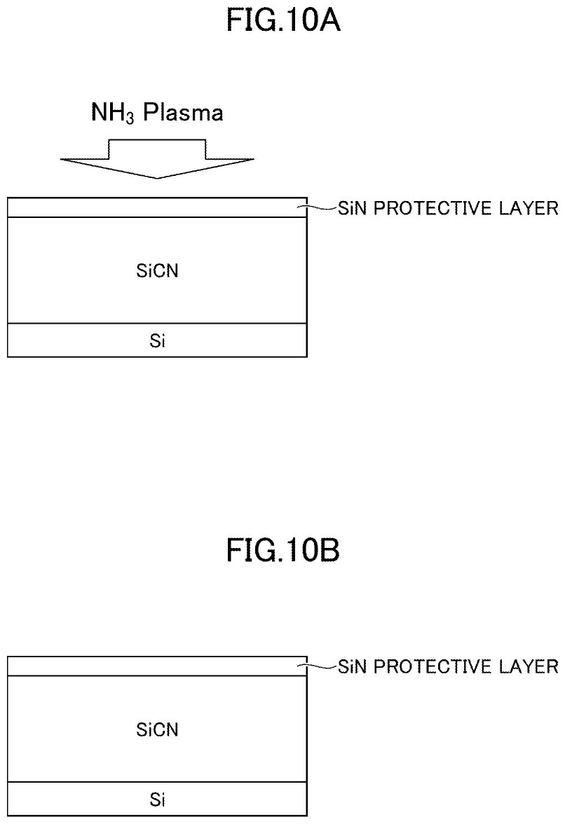

Referring to FIGS. 9 and 10, a mechanism is described in which damage to the SiCN seed layer 101 can be suppressed when the SiN bulk layer 103 is deposited, using a plasma, on the SiCN seed layer 101 that is formed on the substrate W, by the method for forming a film according to the present embodiment.

First, with reference to FIG. 9, a case where the SiN protective layer 102 is not formed on the SiCN seed layer 101 will be described. As illustrated in FIG. 9A, when the Si/SiCN stack is exposed to an NH₃ plasma, the stack reacts with active species such as radicals and ions in the plasma. Thus, carbon (C) contained in the SiCN is desorbed (volatilized) as CHₓ. As a result, the SiCN film thickness is reduced by the amount of region A, as illustrated in FIG. 9B.

Next, with reference to FIG. 10, a case where the SiN protective layer 102 is formed on the SiCN seed layer 101 will be described. As illustrated in FIG. 10A, when the Si/SiCN/SiN protective layer stack is exposed to the NH₃ plasma, the SiN protective layer covering the surface of SiCN prevents the reaction of active species such as radicals and ions in the plasma with the SiCN. Thus, it is possible to prevent carbon (C) contained in SiCN from becoming CHₓ and desorbing (volatilizing). The SiN protective layer contains no carbon (C). Accordingly, even when the SiN protective layer is exposed to an NH₃ plasma, carbon loss is not caused, and the SiN protective layer is not appreciably damaged. As a result, damage to SiCN can be reduced.

### Example

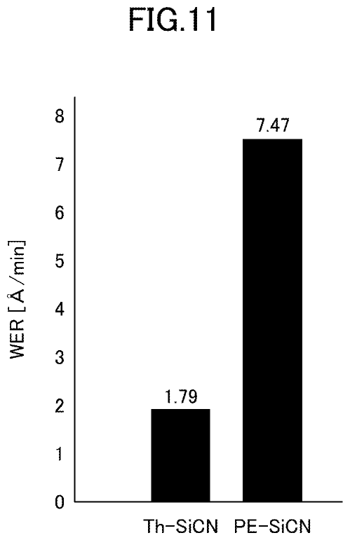

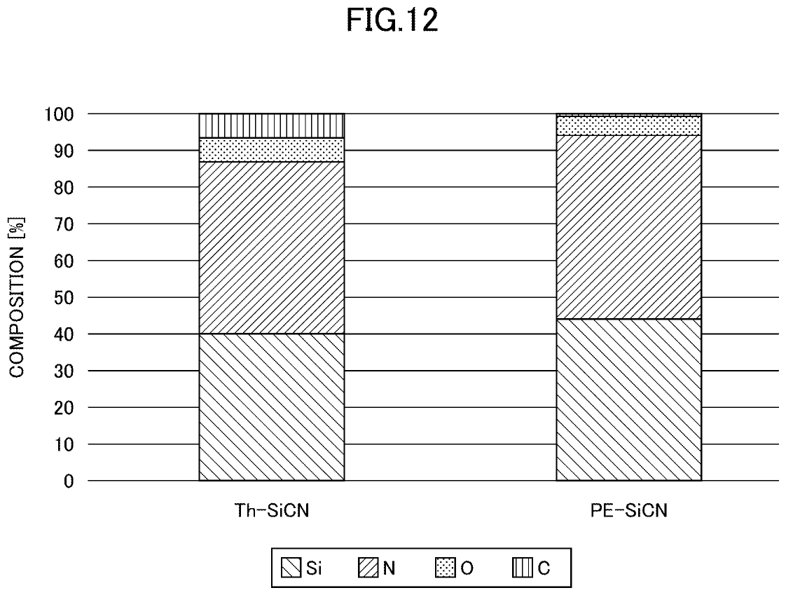

With reference to FIGS. 11 and 12, an example in which plasma resistance of the SiCN seed layer is evaluated will be described.

A SiCN seed layer was formed on a substrate by a thermal ALD. Specifically, the SiCN seed layer was formed on the substrate by performing the process illustrated in FIG. 5.

Also, a SiCN seed layer was formed on the substrate by a plasma enhanced ALD. Specifically, the Th—NH₃ supply step S16 in the process illustrated in FIG. 5 was changed to a step in which the substrate is exposed to a plasma generated from the NH₃ gas, to form a SiCN seed layer on the substrate.

Then, the WER (wet etching rate) of each SiCN seed layer formed on the substrate was measured. The WER is the etching rate when the SiCN seed layer is etched with 0.5% DHF (dilute hydrofluoric acid). In addition, a composition of each SiCN layer formed on the substrate was measured.

FIG. 11 is a diagram illustrating the result of evaluating plasma resistance of the SiCN seed layer. In FIG. 11, the left graph illustrates the WER [Å/min] of the SiCN seed layer (Th—SiCN) formed by the thermal ALD, and the right graph illustrates the WER [Å/min] of the SiCN seed layer (PE-SiCN) formed by the plasma enhanced ALD.

As illustrated in FIG. 11, WER of the SiCN seed layer formed by the thermal ALD is 1.79, while WER of the SiCN seed layer formed by the plasma enhanced ALD is 7.47. That is, the SiCN seed layer formed by the plasma enhanced ALD is about four times greater in WER than the SiCN seed layer formed by the thermal ALD. From this result, it was shown that the film quality of the SiCN layer deteriorates when the SiCN layer is formed using a plasma.

FIG. 12 is a diagram illustrating the result of evaluating a composition of the SiCN seed layer. In FIG. 12, the left graph illustrates the composition [%] of the SiCN seed layer (Th—SiCN) formed by the thermal ALD, and the right graph illustrates the composition [%] of the SiCN seed layer (PE-SiCN) formed by the plasma enhanced ALD.

As illustrated in FIG. 12, the carbon (C) concentration contained in the SiCN seed layer formed by the thermal ALD is approximately 7%, while the carbon (C) concentration of the SiCN seed layer formed by the plasma enhanced ALD is approximately 1%. That is, the SiCN seed layer formed by the plasma enhanced ALD has a significantly lower carbon concentration than the SiCN seed layer formed by the thermal ALD. From this result, it was shown that the concentration of carbon (C) in the SiCN seed layer is reduced when the SiCN layer is formed using a plasma.

These results suggest that when the SiCN seed layer is exposed to a plasma, the concentration of carbon (C) contained in the SiCN seed layer decreases, and thus the film quality deteriorates.

The embodiments disclosed herein should be considered to be exemplary in all respects and not limiting. The embodiments described above may be omitted, substituted, or modified in various forms without departing from the appended claims and spirit thereof.

In the embodiments described above, the processing apparatus is a batch-type apparatus that processes a plurality of substrates at once. The present disclosure is not limited thereto. For example, the processing apparatus may be a sheet-fed apparatus that processes a substrate one by one. For example, the processing apparatus may be a semi-batch apparatus in which a plurality of substrates are disposed on a rotating table in the processing chamber and the substrates are revolved in accordance with the rotation of the rotating table. The substrates are processed by passing through a region in which the first gas is supplied and a region in which the second gas is supplied in turn.

According to the present disclosure, damage to a SiCN layer when forming a SiN layer on the SiCN layer using plasma can be reduced.

1. A method for forming a film, the method comprising:
forming a SiCN seed layer on a substrate by a thermal atomic layer deposition (ALD),
forming a SiN protective layer on the SiCN seed layer by a thermal ALD, and
forming a SiN bulk layer on the SiN protective layer by a plasma enhanced ALD.

2. The method for forming a film according to claim 1, wherein the forming the SiCN seed layer includes supplying a silicon-containing gas to the substrate, supplying a carbon-containing gas to the substrate, and supplying a nitrogen-containing gas to the substrate.

3. The method for forming a film according to claim 2, wherein in the forming the SiCN seed layer, the silicon-containing gas is a HCD gas, the carbon-containing gas is a C₂H₄ gas, and the nitrogen-containing gas is an NH₃ gas.

4. The method for forming a film according to claim 1, wherein the forming the SiN protective layer includes supplying a silicon-containing gas to the substrate and supplying a nitrogen-containing gas to the substrate.

5. The method for forming a film according to claim 4, wherein in the forming the SiN protective layer, the silicon-containing gas is a HCD gas and the nitrogen-containing gas is an NH₃ gas.

6. The method for forming a film according to claim 1, wherein the forming the SiN bulk layer includes supplying a silicon-containing gas to the substrate and exposing the substrate to a plasma generated from a nitrogen-containing gas.

7. The method for forming a film according to claim 6, wherein in the forming the SiN bulk layer, the silicon-containing gas is a DCS gas and the nitrogen-containing gas is an NH₃ gas.

8. The method for forming a film according to claim 1, wherein the forming the SiN bulk layer further includes exposing the substrate to a plasma generated from a H₂ gas.

9. The method for forming a film according to claim 1, wherein the forming the SiCN seed layer, the forming the SiN protective layer, and the forming the SiN bulk layer are performed in a same processing chamber.

10. The method for forming a film according to claim 2, wherein the forming the SiN protective layer includes supplying a silicon-containing gas to the substrate and supplying a nitrogen-containing gas to the substrate.

11. The method for forming a film according to claim 10, wherein the forming the SiN bulk layer includes supplying a silicon-containing gas to the substrate and exposing the substrate to a plasma generated from a nitrogen-containing gas.

12. The method for forming a film according to claim 11, wherein the forming the SiN bulk layer further includes exposing the substrate to a plasma generated from a H₂ gas.

13. The method for forming a film according to claim 12, wherein the forming the SiCN seed layer, the forming the SiN protective layer, and the forming the SiN bulk layer are performed in a same processing chamber.

14. The method for forming a film according to claim 4, wherein the forming the SiN bulk layer includes supplying a silicon-containing gas to the substrate and exposing the substrate to a plasma generated from a nitrogen-containing gas.

15. The method for forming a film according to claim 14, wherein the forming the SiN bulk layer further includes exposing the substrate to a plasma generated from a H₂ gas.

16. The method for forming a film according to claim 15, wherein the forming the SiCN seed layer, the forming the SiN protective layer, and the forming the SiN bulk layer are performed in a same processing chamber.

17. The method for forming a film according to claim 6, wherein the forming the SiN bulk layer further includes exposing the substrate to a plasma generated from a H₂ gas.

18. The method for forming a film according to claim 17, wherein the forming the SiCN seed layer, the forming the SiN protective layer, and the forming the SiN bulk layer are performed in a same processing chamber.

19. The method for forming a film according to claim 8, wherein the forming the SiCN seed layer, the forming the SiN protective layer, and the forming the SiN bulk layer are performed in a same processing chamber.

20. A processing apparatus comprising:
a processing chamber configured to contain a substrate therein,
a gas supply configured to supply a process gas into the processing chamber,
an exhaust configured to exhaust the processing chamber, and
a controller configured to control the gas supply and the exhaust to perform forming a SiCN seed layer on the substrate by a thermal ALD, forming a SiN protective layer on the SiCN seed layer by a thermal ALD, and forming a SiN bulk layer on the SiN protective layer by a plasma enhanced ALD.
